(19) United States
(12) Patent Application Publication
(10) Pub. No.: US 2025/0346052 A1
(43) Pub. Date: Nov. 13, 2025

(54) INKJET PRINTING APPARATUS AND ASSEMBLY METHOD OF THE SAME

(71) Applicant: Samsung Display Co., LTD., Yongin-si (KR)

(72) Inventors: Jungwoong Byun, Yongin-si (KR); YU KONTA, Yongin-si (KR); CHEONG-WAN MIN, Yongin-si (KR)

(21) Appl. No.: 19/185,867

(22) Filed: Apr. 22, 2025

(30) Foreign Application Priority Data
May 9, 2024 (KR) 10-2024-0061386

(51) Int. Cl. B41J 25/34; B41J 2/175; B41J 3/54; B41J 25/00

(52) U.S. Cl. CPC B41J 25/34; B41J 2/175; B41J 3/543; B41J 25/001

(57) ABSTRACT

An inkjet printing apparatus and a method of assembling the same are disclosed. An inkjet printing apparatus includes a first plate extending in a first direction and a second direction, first and second supports extending in a third direction crossing the first direction and the second direction, and located at opposite ends of the first plate, first pickers located at end areas of the first and second supports, second pickers located to have an offset in the third direction with the first pickers at the end areas of the first and second supports, and having greater alignment precision than the first pickers, a second plate extending in the first direction and the second direction and spaced apart from the first plate in the third direction, a fourth plate, and second connection parts located on the fourth plate.

### CROSS-REFERENCE TO RELATED APPLICATION

The present application claims priority to and the benefit of Korean Patent Application No. 10-2024-0061386, filed on May 9, 2024 in the Korean Intellectual Property Office, the entire disclosure of which is incorporated herein by reference.

### BACKGROUND

### 1. Field

Aspects of embodiments of the disclosure relate to an inkjet printing apparatus and a method of assembling the same.

### 2. Description of the Related Art

As information technology develops, the importance of display devices, a connecting medium between users and information, is increased. Accordingly, the use of display devices, such as liquid crystal display devices (“LCD”), organic light emitting display devices (“OLED”), and plasma display devices (“PDP”), is increasing.

A plurality of processes may be performed to form a light-emitting device on a substrate that is included in a display device. For example, an inkjet process may be performed to form a film or a pattern by ejecting ink on the substrate.

As demand for large displays increases, demand for an inkjet printing apparatus for a large-sized substrate also increases. An inkjet printing apparatus for the large-sized substrate may include a large number of heads that eject the ink on the large-sized substrate, and a structure for easily mounting a large number of heads may be desired.

The above information disclosed in this Background section is provided for enhancement of understanding of the background and, therefore, the information discussed in this Background section does not necessarily constitute prior art.

### SUMMARY

According to an aspect of embodiments of the disclosure, an inkjet printing apparatus used to manufacture a display device and a method of assembling the same are provided.

According to an aspect of embodiments of the disclosure, an inkjet printing apparatus with relatively improved head alignment accuracy and easy maintenance is provided.

Aspects of some embodiments include an assembly method of the inkjet printing apparatus is provided.

Additional aspects of some embodiments of the disclosure will be set forth in or understood from the description which follows, and, in part, will be apparent from the description, or may be learned by practice of the inventive concepts.

According to one or more embodiments of the disclosure, an inkjet printing apparatus includes: a first plate extending in a first direction and a second direction, first and second supports extending in a third direction crossing the first direction and the second direction, and located at opposite ends of the first plate, first pickers located at end areas of the first and second supports, second pickers located to have an offset in the third direction with the first pickers at the end areas of the first and second supports, and having greater alignment precision than the first pickers, a second plate extending in the first direction and in the second direction, spaced apart from the first plate in the third direction, first connection parts located on the second plate and connected to the first pickers, to bring the second plate in contact (e.g., close contact) with the first plate, a fourth plate extending in the first direction and the second direction, spaced apart from the second plate in the third direction, and a plurality of heads mounted on an upper surface, and second connection parts located on the fourth plate, and connected to the second pickers to align the fourth plate in the first direction and the second direction.

In one or more embodiments, a first flow path may be defined in the third direction in the first plate, a second flow path may be defined in the third direction in the second plate, and a first end of the first flow path and a second end of the second flow path may communicate if the first plate and the second plate are in contact (e.g., close contact).

In one or more embodiments, the inkjet printing apparatus may further include: an O-ring located on the second plate, and the communicating first end and the second end may be sealed by the O-ring if the second plate moves toward the first plate in an opposite direction to the third direction.

In one or more embodiments, a plurality of flow paths through which an ink flows and connected to each of the plurality of heads and each of the plurality of flow paths may be defined if the second plate is in contact (e.g., close contact) with the first plate.

In one or more embodiments, the second connection parts may include a first second connection part and a second second connection part located at opposite vertices of the fourth plate facing in the first direction, and the first second connection parts defines an origin, and the second second connection parts limits rotational movement of the fourth plate.

In one or more embodiments, the inkjet printing apparatus may further include: a third plate extending in the first direction and the second direction and located on the fourth plate; and a spacer located between the second plate and the third plate, and the spacer may vibratingly separate the second plate and the fourth plate.

In one or more embodiments, the spacer may include an elastic body.

In one or more embodiments, the elastic body may be elastically deformable in the first direction, the second direction, and the third direction.

In one or more embodiments, each of the plurality of heads may be located to have a certain (e.g., preset) angle based on a virtual axis parallel to a scanning direction in which an inkjet printing process is performed.

In one or more embodiments, the inkjet printing apparatus may further include a controller configured to store a position where the second connection parts connect to the second pickers.

According to one or more embodiments of the disclosure, a method of assembling an inkjet printing apparatus includes: locating a head module including a plurality of head modules under a docking module; moving the head module in an opposite direction to a third direction by a first operating distance, and performing primary chucking of the head module by the docking module; forming a flow path as the head module and the docking module come into contact (e.g., close contact); moving the head module in the opposite direction to the third direction by a second operating distance different from the first operating distance, and performing secondary chucking of the head module by the docking module; and aligning the head module in a first direction and a second direction crossing the third direction by the docking module.

In one or more embodiments, the forming of the flow path includes: moving a second plate of the head module that extends in the first direction and the second direction in the opposite direction to the third direction, such that the second plate is in contact (e.g., close contact) with a first plate of the docking module that extends in the first direction and the second direction; and communicating a first end of a first flow path formed in the third direction in the first plate and a second end of a second flow path formed in the third direction in the second plate.

In one or more embodiments, the first end of the first flow path and the second end of the second flow path may be sealed by a rebound elastic force in the forming of the flow path.

In one or more embodiments, the first operating distance may be greater than the second operating distance, and the docking module may chuck the head module using air.

In one or more embodiments, in the primary chucking includes: defining an origin by picking a first end of a fourth plate of the head module that extends in the first direction and the second direction and is spaced apart from the second plate in the third direction, and on which the plurality of heads is mounted on an upper surface; and limiting a rotational movement of the fourth plate by picking a second end facing the first end in the first direction.

In one or more embodiments, the primary chucking and the secondary chucking may be vibrationally separated.

In one or more embodiments, the head module may be formed by forming a third plate on the fourth plate to cover upper portions of the plurality of heads and locating an elastic body on the third plate.

In one or more embodiments, the elastic body may be elastically deformed in the first direction, the second direction, and the third direction.

In one or more embodiments, the method may further include: locating the plurality of heads to have a certain (e.g., preset) angle based on a virtual axis parallel to a scanning direction in which an inkjet printing process is performed before locating the head module under the docking module.

In one or more embodiments, the method may further include: storing a position where the docking module primary chucks the head module, before locating the head module under the docking module.

An inkjet printing apparatus according to one or more embodiments of the disclosure may include the head module, and the docking module to which the head module is docked. The docking module may include the first pickers for automatically detaching the flow path and control line for the ink flow at one time, and the second pickers for precisely aligning the head. Accordingly, the inkjet printing apparatus and the assembly method thereof may precisely attach and detach the head module, and, in case that the head module is attached/detached, the time to attach and detach the flow path and the control line may be reduced.

In addition, the head module may be located according to a certain value (e.g., a preset value) to ensure repeatability. Accordingly, the reliability of a patterning process using the inkjet printing apparatus may be ensured.

In addition, the inkjet printing apparatus and the assembly method thereof may be free from alignment of the head module and automatic attachment and dismounting of the flow path and the control line, or the like. To this end, the first connection parts to which the first pickers performing the alignment may be connected are placed on the second plate, and the second connection parts to which the second pickers performing the automatic attachment and removal are connected are placed on the fourth plate flexibly connected to the second plate, and between the second plate and the fourth plate, the third plate, and the elastomer located on the third plate may be placed.

In addition, the inkjet printing apparatus and the assembly method thereof may be located at the angle such that a timing of a use of the plurality of nozzles included in the head module does not overlap with a vertical reference line parallel to a scan direction.

It is to be understood that both the foregoing general description and the following detailed description are explanatory and are intended to provide further explanation of the invention.

### BRIEF DESCRIPTION OF THE DRAWINGS

The accompanying drawings, which are included to provide a further understanding of the invention and are incorporated in and constitute a part of this specification, illustrate some embodiments of the invention, and together with the description serve to explain the invention.

FIG. 1 is a view illustrating an inkjet printing apparatus according to one or more embodiments of the disclosure.

FIGS. 2 and 3 are views illustrating pickers included in the inkjet printing apparatus of FIG. 1.

FIG. 4 is a view illustrating connection parts included in the inkjet printing apparatus of FIG. 1.

FIG. 5 is a block diagram illustrating a controller of the inkjet printing apparatus of FIG. 1.

FIG. 6 is a perspective view illustrating an arrangement structure of a plurality of head packs included in head modules of FIG. 1.

FIG. 7 is a view illustrating a head included in the inkjet printing apparatus of FIG. 1.

FIG. 8 is a view illustrating a plurality of flow paths included in the inkjet printing apparatus of FIG. 1.

FIG. 9 is a view illustrating an arrangement of a plurality of heads mounted on a head module of FIG. 6.

FIGS. 10 and 11 are views illustrating a scanning direction of the inkjet printing apparatus of FIG. 1.

FIGS. 12 to 16 are views illustrating an assembly method of an inkjet printing apparatus according to one or more embodiments of the disclosure.

### DETAILED DESCRIPTION

Herein, some embodiments of the disclosure will be described in further detail with reference to the attached drawings. Same reference numerals will be used for the same components in the drawings, and some repeated descriptions of the same components may be omitted.

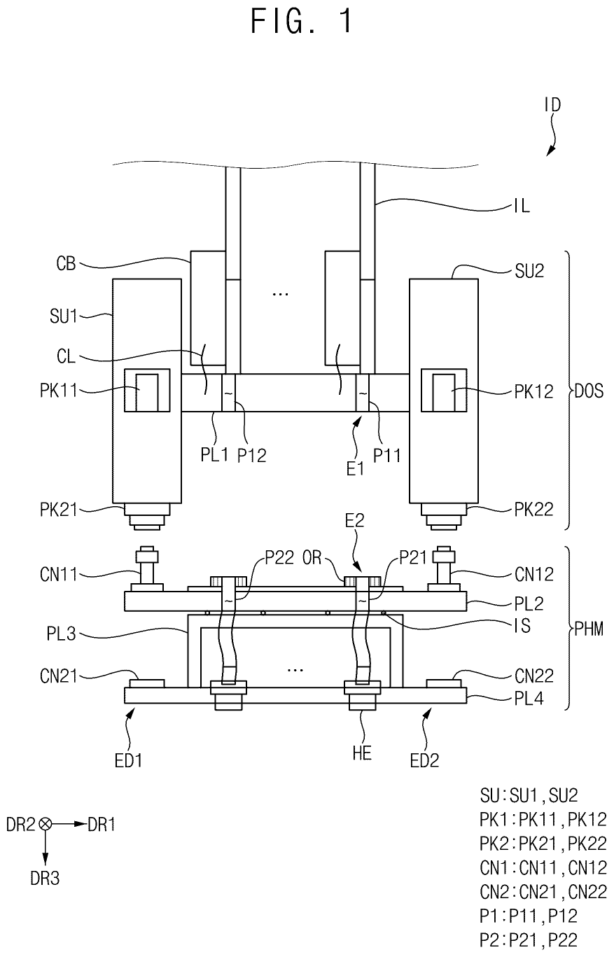

FIG. 1 is a view illustrating an inkjet printing apparatus according to one or more embodiments of the disclosure.

Referring to FIG. 1, an inkjet printing apparatus ID may be an inkjet printing apparatus for a large-sized substrate.

For example, a large-sized substrate may refer to a substrate being manufactured on which a display device is formed by forming a plurality of devices, lines, or the like, on a base substrate. For example, the large-sized substrate may be about 2.5 m×about 2.5 m. For example, the large substrate may include a glass.

However, the disclosure is not limited to thereto. For example, usage, size, material, or the like of the large-sized, or large, substrate may be variously changed.

For example, the inkjet printing apparatus ID may be an area inkjet printer that forms a single layer on the large substrate. However, the disclosure is not limited thereto. For example, the inkjet printing apparatus ID may be a pattern inkjet printer that forms a pre-set pattern on the large substrate.

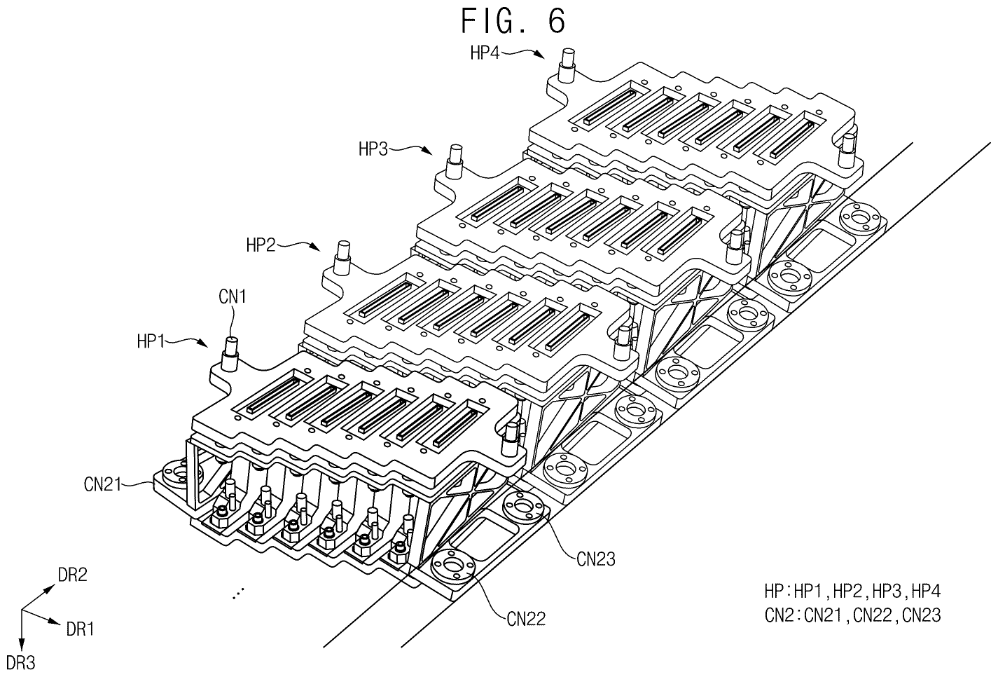

For example, in the case of the inkjet printing apparatus ID for the large substrate, a plurality of nozzles may be included to increase discharge amounts and discharge speed on the large substrate. The plurality of nozzles may be defined in a head. The inkjet printing apparatus ID for the large substrate may include a plurality of heads HE. The plurality of heads HE may be packaged in a certain (e.g., preset) number to form one head pack (e.g., a head pack HP of FIG. 6). For example, one head pack may include about six heads. However, the disclosure is not limited thereto. For example, the number of heads included in one head pack may vary.

The inkjet printing apparatus ID for the large substrate may include the plurality of head packs. For example, in a case of the inkjet printing apparatus including one head, only the one head needs to be aligned. However, in a case of the inkjet printing apparatus ID for the large substrate, the plurality of heads and/or the plurality of head packs need to be aligned. If an alignment of the plurality of heads and/or the plurality of head packs is misaligned, printing quality may be deteriorated.

The inkjet printing apparatus ID according to one or more embodiments of the disclosure may have relatively improved head alignment precision and be easily maintained. To this end, in one or more embodiments, the inkjet printing apparatus ID may include a docking module DOS and a head module PHM.

In one or more embodiments, the docking module DOS may include supports SU including a first plate PL1, a first support SU1, and a second support SU2, first pickers PK1, and second pickers PK2.

In one or more embodiments, the first plate PL1 may extend in a first direction DR1 and a second direction DR2. For example, the second direction DR2 may cross the first direction DR1. For example, the second direction DR2 may be perpendicular to the first direction DR1.

For example, the first plate PLA may include a first surface (e.g., an upper surface) and a second surface (e.g., a lower surface) opposite in a third direction DR3.

For example, the third direction DR3 may cross both the first direction DR1 and the second direction DR2. For example, the third direction DR3 may be perpendicular to both the first direction DR1 and the second direction DR2. For example, the third direction DR3 may refer to a direction of gravity, a vertical direction, a direction in which an ink is ejected, or the like.

For example, the first surface may be spaced apart from the head module PHM in an opposite direction of the third direction DR3 and may be adjacent to an ink supply line IL to which the ink is supplied. For example, a component connected to the ink supply line IL may be located on the first surface. For example, in a case in which the first plate PL1 includes a metal, the component may include a nipple. For example, the nipple may include a chemically resistant material and may be fit-fitted to the ink supply line IL. However, the disclosure is not limited thereto. For example, the component may be variously changed.

For example, the second surface may be adjacent to the head module PHM. For example, the second surface may be surface-processed (e.g., polished, or the like) to improve adhesion with a second plate PL2 described below.

In one or more embodiments, a first flow path P1 may be formed in the third direction DR3 in the first plate PL1. For example, the ink may be delivered from the ink supply line IL to the first flow path P1 in the third direction DR3.

In one or more embodiments, a plurality of paths (e.g., a first first path P11, a second first path P12, or the like) may be formed in the first plate PL1. The plurality of paths may be connected to each of the plurality of heads HE. Accordingly, the ink may be delivered to each of the plurality of heads HE. In one or more embodiments, each of the plurality of paths may be connected to the plurality of heads HE, respectively, and may be a part of a path through which the ink flows.

In one or more embodiments, the supports SU may include the first support SU1 and the second support SU2. The first support SU1 and the second support SU2 may extend in the third direction DR3 and be located at opposite ends of the first plate PL1.

In an embodiment, when viewed from a side, each of the first support SU1 and the second support SU2 may be symmetrically located at two ends of the first plate PL1. The first plate PL1 may be a horizontal plate connecting the first support SU1 and the second support SU2 located at the two ends.

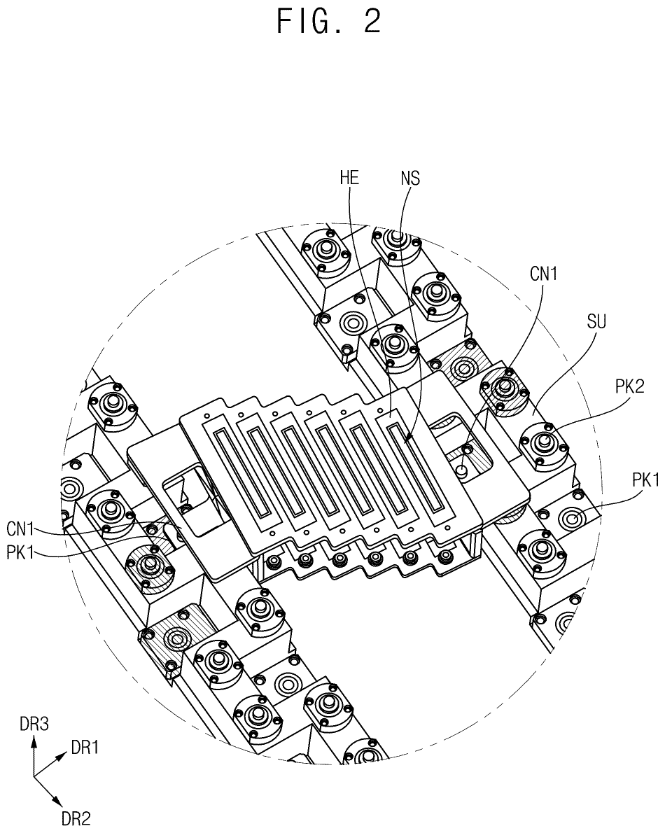

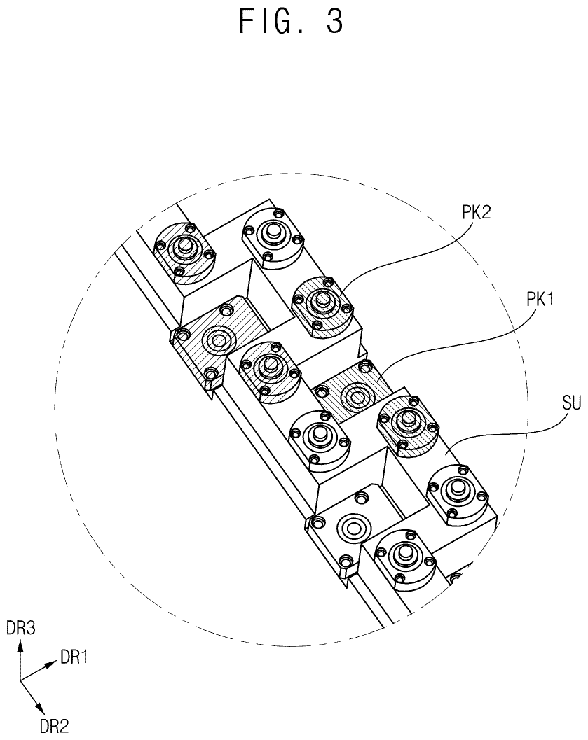

FIGS. 2 and 3 are views illustrating pickers included in the inkjet printing apparatus of FIG. 1.

Referring to FIGS. 1 and 2, in one or more embodiments, the first pickers PK1 may be located at end regions of the first support SU1 and the second support SU2. When viewed from the side, the first pickers PK1 may be located to act at an upper end in the vertical direction in a case in which the head module PHM is pulled. For example, the side may be defined by the first direction DR1 and the third direction DR3.

For example, the first pickers PK1 may be irrelevant to a precise position determination. For example, if both the first pickers PK1 and the second pickers PK2 are involved in a precise position determination, an error due to over-constraint may occur. For example, because it is ambiguous as to which of the pickers (e.g., the first pickers PK1 or the second pickers PK2) the position determination is performed by, an error determined to be an incorrect position may occur in the inkjet printing apparatus ID. To avoid the error due to the over-constraint, the first pickers PK1 may only perform the role of pulling the second plate PL2 and the precise position determination may be performed only by the second pickers PK2 described below.

In one or more embodiments, the first pickers PK1 may include an air chuck, respectively. For example, first pickers PK1 may include a coarse air chuck having a long operating distance, respectively. For example, the coarse air chuck may include two air lines (e.g., a first air line and a second air line). For example, in a case in which the air is introduced into the first air line, first connection parts CN1 described below may be pulled. On the other hand, in a case in which the air is introduced into the second air line, the first connection parts CN1 may be pushed out.

However, the disclosure is not limited thereto. For example, the first pickers PK1 have been described as including the two air lines so as to have a basic holding torque even when an equipment is stopped; however, a structure, operating principle, or the like of the first pickers PK1 may be changed in various ways.

In one or more embodiments, the second pickers PK2 may be located at the end regions of the first support SU1 and second support SU2 with an offset in the third direction DR3 from the first pickers PK1. For example, when viewed from the side, the second pickers PK2 may be located at a position with a certain (e.g., preset) offset in the third direction DR3 from the first pickers PK1.

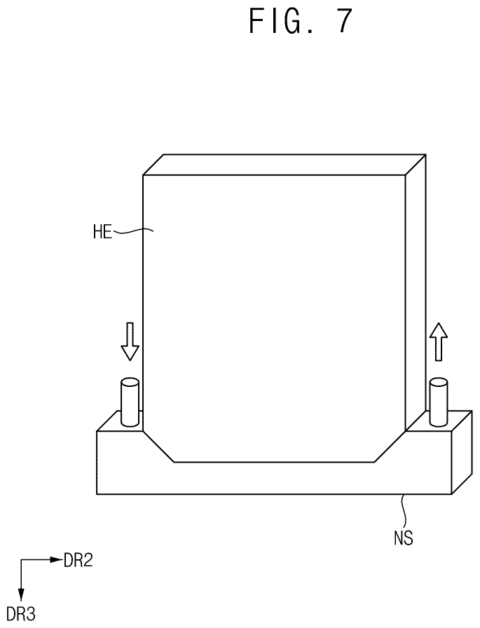

When viewed from the side, the second pickers PK2 may be located close to a nozzle surface (e.g., refer to a nozzle surface NS of FIGS. 2 and 7). For example, if the second pickers PK2 are located too far apart from the nozzle surface, positioning accuracy may be reduced. Therefore, the second pickers PK2 may be located at a position adjacent to the nozzle surface.

In one or more embodiments, each of the second pickers PK2 may include an air chuck. For example, each of the second pickers PK2 may include a fine air chuck having a high positioning precision. For example, the fine air chuck may include two air lines. For example, if the air is introduced into one air line, second connection parts CN2 described below may be pulled. On the other hand, if the air is introduced into the other remaining air line, the second connection parts CN2 may be pushed out.

However, the disclosure is not limited thereto. For example, although the fine air chuck has been described as including the two air lines so as to have the basic holding torque even when the equipment is stopped, a structure, an operating principle, or the like, of the fine air chuck may be variously changed.

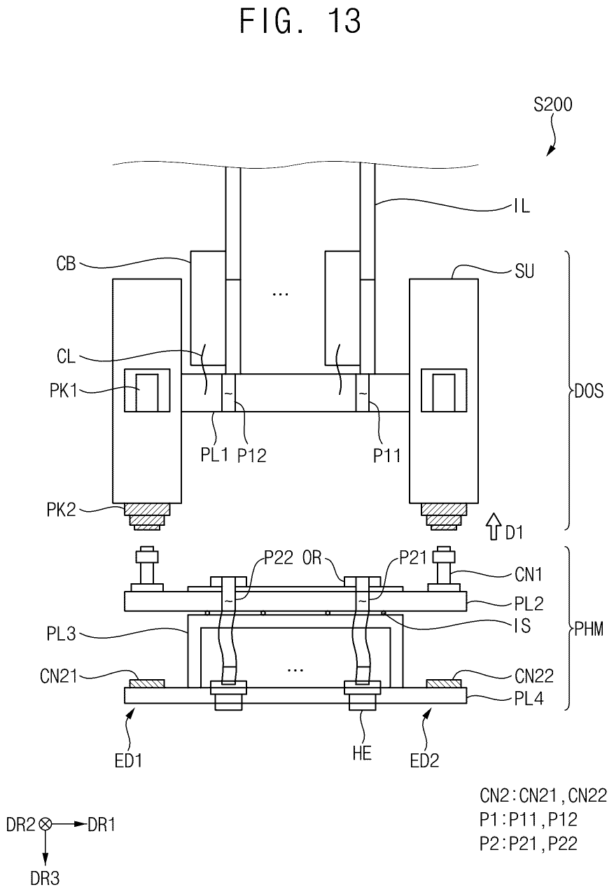

In an embodiment, the first pickers PK1 may have a first operating distance (e.g., a first operating distance D1 of FIG. 13), and the second pickers PK2 may have a second operating distance (e.g., a second operating distance D2).The first operating distance may be greater than the second operating distance. In addition, in an embodiment, alignment precision of the second pickers PK2 may be greater than alignment precision of the first pickers PK1. As described above, the first pickers PK1 may pull the second plate PL2, and a precise position decision may be performed by only the second pickers PK2.

As shown in FIG. 1, the first support SU1 and the second support SU2 are disposed at both, or opposite, ends of the first plate PL1 with the first plate PL1 interposed therebetween, such the inkjet printing apparatus ID of FIG. 1 may include four second pickers PK2 and two first pickers PK1.

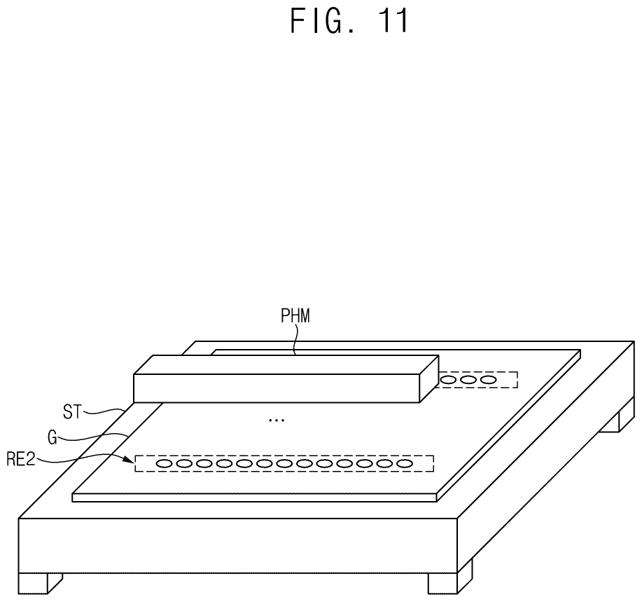

As shown in FIG. 2, based on the first support SU1 and the second support SU2, the two second pickers PK2 spaced apart from each other in the second direction DR2 may configure a chucking system for precise positioning. In addition, based on the first support SU1 and the second support SU2, the one first picker PK1 located between the two second pickers PK2 may configure an automatic attachment/detachment chucking system. A further detailed description of the chucking system for the precise positioning and the chucking system for automatic attachment and detachment will be described below with reference to FIGS. 11, 12, and 13.

Referring again to FIG. 1, in one or more embodiments, the head module PHM may include the second plate PL2, an O-ring OR, the first connection parts CN1, a spacer IS, a third plate PL3, a fourth plate PL4, and the second connection parts CN2.

In one or more embodiments, the second plate PL2 may extend in the first direction DR1 and the second direction DR2, and may be located to be spaced apart from the first plate PL1 in the third direction DR3.

For example, the second plate PL2 may include a third surface (e.g., an upper surface) and a fourth surface (e.g., a lower surface) opposite in the third direction DR3.

For example, the third surface may be adjacent to the docking module DOS.

For example, the fourth surface may be spaced apart from the docking module DOS. For example, the nipple may be located on the fourth surface. For example, the nipple may be fitted with an inlet included in each of the plural heads HE.

In one or more embodiments, a second flow path P2 may be formed in the second plate PL2 in the third direction DR3. For example, the ink may be transferred from the ink supply line IL in the third direction DR3 to the second flow path P2. The ink may be transferred from the second flow path P2 in the third direction DR3 to the inlet. The ink transferred to the inlet may be discharged through the nozzle toward the large substrate.

In one or more embodiments, a plurality of flow paths (e.g., a first second flow path P21, a second second flow path P22, or the like) may be formed in the second plate PL2. The plurality of flow paths may be connected to each of the plurality of heads HE. Accordingly, the ink may be delivered to each of the plurality of heads HE. In one or more embodiments, each of the plurality of flow paths may be connected to each of the plurality of heads HE and may be part of the path through which the ink flows.

In one or more embodiments, if the first plate PL1 and the second plate PL2 are in contact (e.g., close contact), a first end E1 of the first flow path P1 and a second end E2 of the second flow path P2 may be in communication.

In one or more embodiments, the O-ring OR may be disposed on the second plate PL2. For example, the O-ring OR may be disposed on the third surface. In one or more embodiments, if the second plate PL2 moves toward the first plate PL1 in the opposite direction to the third direction DR3, the first end E1 and the second end E2 communicated by the O-ring OR may be sealed.

For example, the first end E1 of the first first flow path P11 may communicate with the second end E2 of the first second flow path P21. Similarly, a third end of the second first flow path P12 may communicate with a fourth end of the second second flow path P22. The third end and the fourth end may be sealed by the O-ring OR.

In one or more embodiments, the inkjet printing apparatus ID may include the plurality of flow paths. Each of the plurality of flow paths may be defined concurrently (e.g., simultaneously) if the second plate PL2 is in contact (e.g., close contact) with the first plate PL1. In one or more embodiments, the second plate PL2 may be pulled by the first pickers PK1, such that the second plate PL2 may come into contact (e.g., close contact) with the first plate PL1, and each the plurality of flow paths may be defined (e.g. completed or formed) at the same time.

For example, the flow path formed by communicating the first end and the second end and the flow path formed by communicating the third end and the fourth end may be defined concurrently (e.g., simultaneously) if the second plate PL2 is in contact (e.g., close contact) with the first plate PL1.

For example, if a cross-sectional area of each of the plurality of flow paths changes, bubbles may be generated in the ink flowing through the plurality of flow paths, or the characteristics of the ink may change.

For example, to keep the cross-sectional area of each of the plurality of flow paths constant, the flow paths may be connected/separated by the O-rings OR. However, the disclosure is not limited thereto. For example, components defining the plurality of flow paths may be varied. For example, an automatic opening/closing part (e.g., a chemical auto coupler of a check valve type, or the like) may be further disposed at the end of each of the plurality of flow paths.

For example, in a case in which viscosity of the ink is high, the connection/separation of the plurality of flow paths may be performed without removing the ink. However, the disclosure is not limited thereto. For example, in a case in which the viscosity of the ink is low, the ink may be removed from the flow path, and then the flow path may be connected/separated.

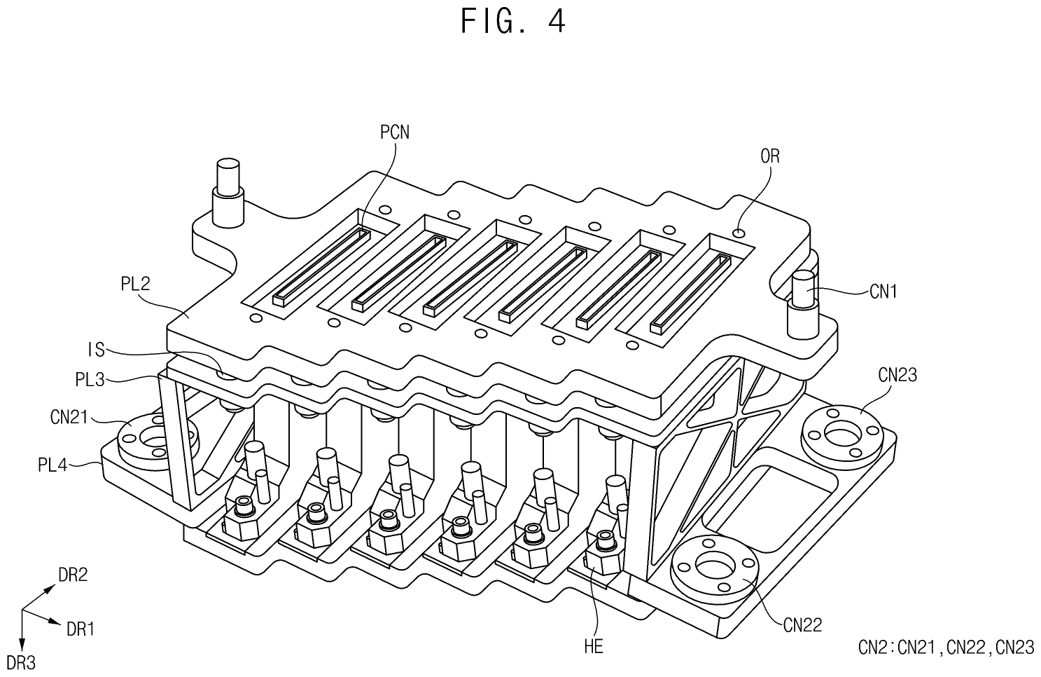

FIG. 4 is a view illustrating connection parts included in the inkjet printing apparatus of FIG. 1.

Referring to FIGS. 1 and 4, in one or more embodiments, the first connection parts CN1 may be disposed on the second plate PL2 and the second plate PL2 may be brought in contact (e.g., close contact) with the first plate PL1 by connecting the first pickers PK1.

For example, in a case in which the first connection parts CN1 are connected to the first pickers PK1, the second plate PL2 moves toward the first plate PL1 in the opposite direction to the third direction DR3, and, as the second plate PL2 is in contact (e.g., close contact) with the first plate PL1, the plurality of flow paths may be automatically defined at the same time. Accordingly, maintenance, repair, and/or management of the inkjet printing apparatus ID may be easy.

In one or more embodiments, the third plate PL3 may extend in the first direction DR1 and the second direction DR2 and may be spaced apart from the second plate PL2 in the third direction DR3.

For example, the third plate PL3 may include a fifth surface (e.g., an upper surface) and a sixth surface (e.g., a lower surface) opposite in the third direction DR3. For example, the fifth surface may be adjacent to or facing the second plate PL2. For example, the sixth surface may be adjacent to the fourth plate PL4. For example, the third plate PL3 may be disposed on the fourth plate PL4, which will be described below, and may have an inverted “U” shape that may pass over a top of the plurality of head packs (e.g., the plurality of head packs HP of FIG. 4). However, the disclosure is not limited thereto. For example, the third plate PL3 may be disposed on the fourth plate PL4 and may have ay of various shapes that may pass over the plurality of head packs (e.g., the plurality of head packs HP of FIG. 4).

In one or more embodiments, the spacer IS may be disposed between the second plate PL2 and the third plate PL3. For example, the spacer IS may be disposed on the fifth surface. Accordingly, for example, the third plate PL3 may place the second plate PL2 at a relatively higher position than the fourth plate PL4.

In one or more embodiments, the spacer IS may vibratingly separate the second plate PL2 and the fourth plate PL4. For example, the second plate PL2 and the third plate PL3 may have high rigidity, not coupled, and may be connected in a flexible structure by the spacer IS.

In one or more embodiments, the separator IS may include an elastomer. For example, the elastomer may include a rubber, a spring, or the like. These may be used alone or in combination with each other. For example, the elastomer including the rubber may have a tube form. As another example, the spring may have a spiral shape. However, the disclosure is not limited to thereto. For example, a material, a structure, or the like included in the separator IS may be variously changed. In another example, the separator IS may be omitted. In this case, there may be a swinging free space between the second plate PL2 and the third plate PL3. In one or more embodiments, the elastomer may be elastically modified in the first direction DR1, the second direction DR2, and/or the third direction DR3.

In one or more embodiments, the spacer IS may vibratingly separate the second plate PL2 and the fourth plate PL4. Accordingly, the communication of the plurality of flow paths might not affect the precise alignment of the plurality of heads HE.

In one or more embodiments, the fourth plate PL4 may extend in the first direction DR1 and the second direction DR2 and may be spaced apart from the second plate PL2 in the third direction DR3. When viewed from the side, the second plate PL2 may be disposed below the first plate PL1, the third plate PL3 may be disposed below the second plate PL2, and the fourth plate PL4 may be disposed below the third plate PL3. On the other hand, as described above, the first plate PL1 and the second plate PL2 may contact each other while moving in the third direction DR3.

For example, the fourth plate PL4 may include a seventh surface (e.g., an upper surface) and an eighth surface (e.g., a lower surface) opposite in the third direction DR3. The seventh surface may be adjacent to or facing the docking module DOS, and the eighth surface may be spaced further from the docking module DOS than the seventh surface.

In one or more embodiments, the plurality of head packs (e.g., the plurality of head packs HP of FIG. 4) may be mounted on an upper surface (e.g., the seventh surface) of the fourth plate PL4. In one or more embodiments, each of the plurality of head packs may include the plurality of heads HE, and each of the plurality of heads HE may include the nozzle that discharges the ink.

The fourth plate PL4 may support the plurality of heads HE. The plurality of heads HE may be located on the fourth plate PL4. For example, the plurality of heads HE may be located side by side in the first direction DR1 and the second direction DR2 on the fourth plate PL4.

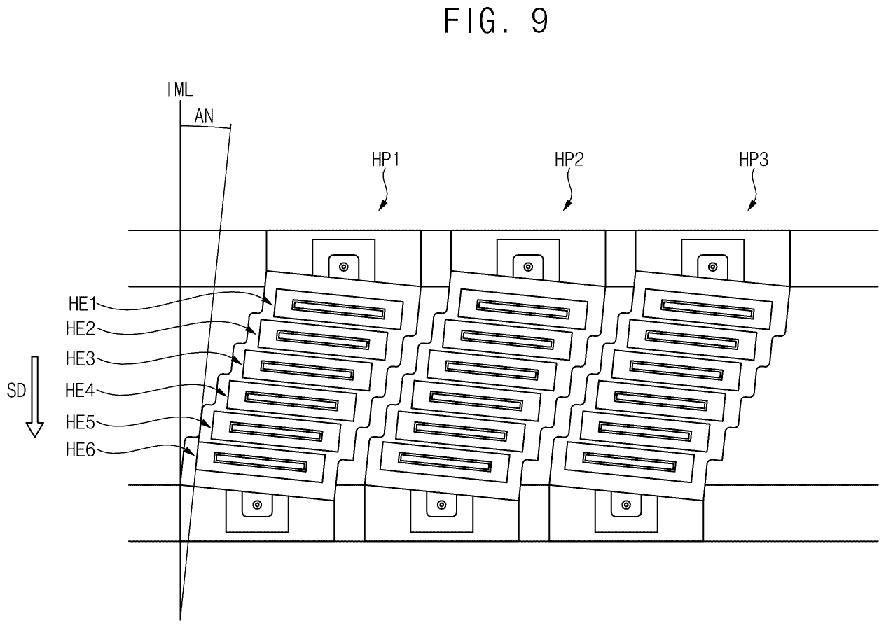

For example, the plurality of heads HE may be located side by side in the horizontal direction. However, the disclosure is not limited thereto. For example, as shown in FIG. 9, the plurality of heads HE may be located at an angle.

For example, one head pack may include about six heads HE. However, the disclosure is not limited thereto. For example, the number of heads HE included in the one head pack may be varied. For example, the plurality of heads HE may include two or more (except six).

For example, the tube nipple may be disposed on the eighth surface. The tube nipple may be disposed to connect the flow path to each of the plurality of heads. Accordingly, the ink may be provided to each of the plurality of heads.

In one or more embodiments, the second connection parts CN2 may be disposed on the fourth plate PL4. The second connection parts CN2 may be disposed at vertices that do not interfere with the plurality of head packs.

In one or more embodiments, the second connection parts CN2 may be connected to the second pickers PK2 to align the fourth plate PL4 in the first direction DR1 and the second direction DR2.

In one or more embodiments, the second connection parts CN2 may include a first second connection part CN21 and a second second connection part CN22 disposed at both, or opposite, vertices of the fourth plate PL4 in the first direction DR1. The first second connection part CN21 may define an origin. The second second connection part CN22 may limit rotational movement of the fourth plate PL4.

However, the disclosure is not limited thereto. For example, the second connection parts CN2 may further include a third second connection part CN23. The third second connection part CN23 may be plural. For example, the plurality of third second connection parts CN23 may be placed on the top of the head module PHM. The plurality of third second connection parts CN23 may be placed at both, or opposite, vertices opposite in the first direction DR1. The third second connection parts CN23 may be spaced apart from both the first second connection CN21 and the second second connection parts CN22 in the second direction DR2. The third second connection parts CN23 may not be involved in the precise positioning and may act in a role of pulling the fourth plate PL4.

For example, in a case in which the inkjet printing apparatus ID further includes the third second connection parts CN23, vibration stability according to the weight of the plurality of head packs may be further relatively improved. In a case in which the third second connection parts CN23 is included with respect to a case in which only the first second connection parts and the second second connection parts are included, the weight of the plurality of heads HE becomes heavier. Even so, the fourth plate PL4 may be pulled to become more vibrationally stable. In other words, the head module PHM may be docked more stably to the docking module DOS.

The inkjet printing apparatus ID of FIGS. 1 to 4 are provided as examples, and components of the inkjet printing apparatus ID may be changed, added, or omitted in various ways.

For example, a driver board CB may be further disposed on the first plate PL1. For example, the driver board CB may include a control line CL that transmits signals to each of the plurality of heads HE included in the head module PHM. In an embodiment, an electrical signal provided from the driver board CB may be provided to each of the plurality of heads HE through the control line CL.

For example, after the control line is firstly connected to a connector PCN of each of the plurality of print heads HE, the chucking system for precise positioning (e.g., the second pickers PK2 and the second connection parts CN2) and the automatic attachment/detachment chucking system (e.g., the first pickers PK1 and the first connection part CN1) may operate. However, the disclosure is not limited thereto.

In another example, contact-type signal connection components may be further disposed on the driver board. For example, the contact type component may include a pogo pin, a pin socket, or the like.

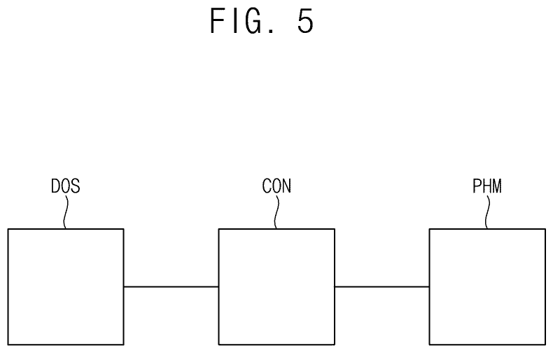

FIG. 5 is a block diagram illustrating a controller CON of the inkjet printing apparatus ID of FIG. 1.

Referring to FIGS. 1 and 5, each of the docking module DOS and head module PHM included in the inkjet printing apparatus ID may be controlled by the controller CON.

In one or more embodiments, the controller CON may store a location where the second connection parts CN2 connect to the second pickers PK2. For example, the second connection parts CN2 and the second pickers PK2 may be connected only at the location. The position might not change each time the plurality of heads HE is aligned. Accordingly, the alignment repeatability (i.e., the positioning precision) may be increased.

For example, the controller CON may store absolute coordinates where the second connection parts CN2 and the second pickers PK2 are connected.

However, this is provided as an example, and the controller CON can control various operations of each of the docking module DOS and head module PHM.

FIG. 6 is a perspective view illustrating an arrangement structure of a plurality of head packs included in head modules of FIG. 1.

Referring to FIGS. 1 and 6, for example, the inkjet printing apparatus ID may include a plurality of head packs HP. For example, the plurality of head packs HP may include a first head pack HP1, a second head pack HP2, a third head pack HP3, a fourth head pack HP4, or the like. The first head pack HP1, the second head pack HP2, the third head pack HP3, and the fourth head pack HP4 may be located in a direction (e.g., the second direction DR2).

However, the disclosure is not limited thereto. In an embodiment, the head module PHM may perform the inkjet process while moving only in the first direction DR1.

For example, a length of the plurality of head packs HP in the second direction DR2 may be the same or substantially the same as a length of a side of the large substrate. Accordingly, the inkjet printing apparatus ID may perform printing only in the first direction DR1.

FIG. 6 is shown as an example, however, and a number of the head packs HP included in the head module PHM, the number of heads HE included in each of the plurality of head packs HP, and the number of plural nozzles included in each of the plurality of heads HE may be changed in various ways.

For example, in a case in which the inkjet printing apparatus ID is the inkjet printing apparatus for the large substrate, the plurality of head packs HP may be located side by side in the first direction DR1 and the second direction DR2.

In an embodiment, the first head pack HP1, the second head pack HP2, the third head pack HP3, and the fourth head pack HP4 include the same or substantially the same configuration and, for convenience of explanation, the explanation will focus on the first head pack HP1.

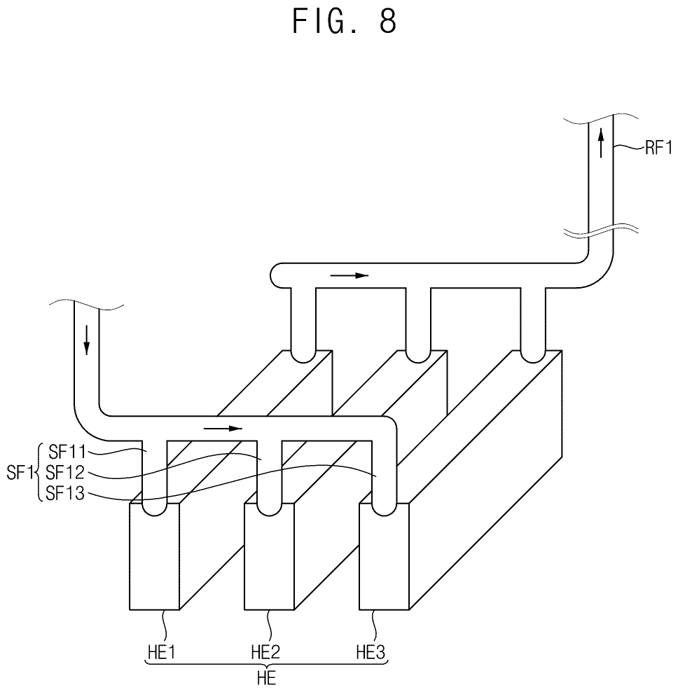

FIG. 7 is a view illustrating the head included in the inkjet printing apparatus of FIG. 1. FIG. 8 is a view illustrating a plurality of flow paths included in the inkjet printing apparatus of FIG. 1.

Referring to FIGS. 1, 6, 7, and 8, for example, if the inkjet printing apparatus includes a plurality of head packs HP (and/or a plurality of heads HE), changing one or more among the plurality of head packs HP (and/or the plurality of heads HE) may be difficult.

Multiple head packs HP (and/or multiple heads HE) may be spatially difficult to access, and if the multiple head packs HP (and/or multiple heads HE) need to be replaced, such that a plurality of lines (e.g., an ink supply line, an ink recovery line, a control line, or the like) must be connected to each of the head packs HP (and/or a plurality of heads HE), maintenance/repair or the like of the inkjet device may take a long time.

In addition, while the plurality of lines is connected to each of the head packs HP, the alignment of the head packs HP may be misaligned. Accordingly, the ink may be ejected to an unintended area on the substrate, resulting in poor display quality (e.g., dark spots, or the like).

In a case of the inkjet printing apparatus according to a comparative example, a gap between the head packs HP may be large, such that the operator may replace the plurality of head packs HP. In this case, there may be a problem that the facility becomes larger, a manufacturing cost of the facility increases, and the facility placement area is large.

The docking module DOS included in the inkjet printing apparatus ID according to one or more embodiments of the disclosure may include the first pickers PK1 and second pickers PK2. The first pickers PK1 may connect the plurality of lines at once, and the second pickers PK2 may precisely align the head module PHM.

For example, the first head pack HP1 may include the first connection parts CN1 and the second connection parts CN2. For example, the second connection parts CN2 may include the first second connection part CN21, the second second connection part CN22, and the third second connection part CN23. As described above, the first second connection part CN21 may define the origin. The second second connection part CN22 may constrain a degree of freedom of the rotation while looking at the origin. Accordingly, the fourth plate PL4 may not rotate. The third second connection part CN23 may pull the fourth plate PL4. Accordingly, even if the weight of the plural heads HE becomes heavier, the fourth plate PL4 may be pulled more vibratingly stable.

For example, the plurality of heads HE may be connected to the plurality of flow paths through which the ink is supplied. For example, the ink may be introduced into each of the plurality of heads HE in the third direction DR3. The ink may be ejected from the nozzle surface NS toward the substrate. Each of the plurality of heads HE may be connected to a flow path for recovering remaining ink. The remaining ink may refer to a difference between the ink supplied to each of the plurality of heads HE and the ink ejected toward the large substrate. The remaining ink may be recovered and reused.

For example, each of the heads HE may be connected to a plurality of supply flow paths SF1. For example, the plurality of heads HE may include a first head HE1, a second head HE2, and a third head HE3. For example, the plurality of supply flow paths SF1 may include a first supply flow path SF11, a second supply flow path SF12, and a third supply flow path SF13.

For example, the ink may be introduced into each of the plurality of heads HE through the plurality of supply flow paths SF1. For example, the ink may be introduced into the first head HE1 through the first supply flow path SF11. The ink may be introduced into the second head HE2 through the second supply flow path SF12. The ink may be introduced into the third head HE3 through the third supply flow path SF13.

The remaining ink may be recovered through a plurality of recovery flow paths RF1. For example, the remaining ink after ejecting the ink on the substrate from each of the first head HE1, the second head HE2, and the third head HE3 (i.e., the remaining ink) may be collected by the plurality of recovery flow paths RF1, may be returned to the inkjet printing apparatus ID through the flow paths RF1, and may be reused.

The inkjet printing apparatus ID of FIG. 8 is an example of a circulating inkjet printing apparatus; however, the disclosure is not limited thereto. For example, in a case in which the inkjet printing apparatus ID of FIG. 8 is a non-circulating inkjet printing apparatus, the non-circulating inkjet printing apparatus may further include a plurality of second supply flow paths instead of the plurality of recovery flow paths RF1. Like the plurality of supply flow paths SF1, the plurality of second supply flow paths may be flow paths through which the ink is introduced into the plurality of heads HE.

In the case of the inkjet printing apparatus for the large substrate according to the comparative example, an operator connects the plurality of flow paths, and the control lines connected to each of the plurality of the head packs. Therefore, in a case in which the replacement of the head module PHM is necessary in the inkjet printing apparatus for the large substrate according to the comparative example, the replacement may take a long time and deteriorated quality of the inkjet process due to the human error (e.g., a problem because the operator may not accurately connect the plurality of flow paths (and/or the control lines), or the like) may occur.

However, in the inkjet printing apparatus ID according to one or more embodiments of the disclosure, the plurality of flow paths (and/or the control lines or the like) may be concurrently (e.g., simultaneously) connected by contact (e.g., close contact) between the first plate PL1 and the second plate PL2. Accordingly, a replacement time may be reduced. In addition, by repeatedly attaching and detaching the head module PHM at a mechanically set position, the occurrence of a human error or the like may be prevented.

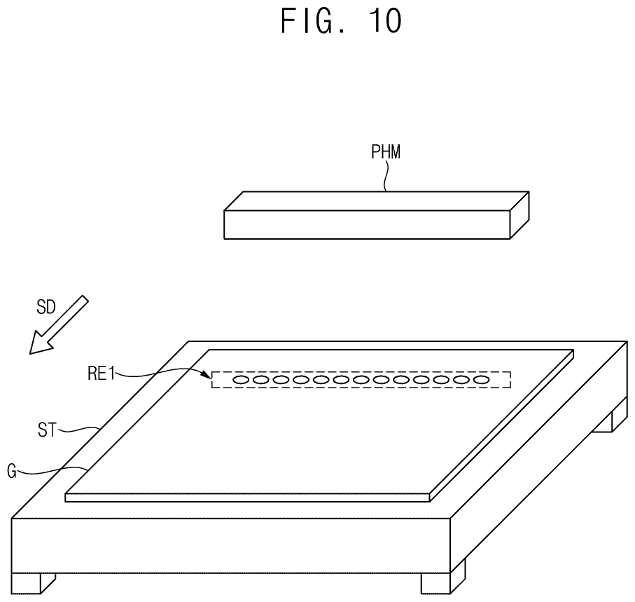

FIG. 9 is a view illustrating an arrangement of a plurality of heads mounted on the head module of FIG. 6. FIGS. 10 and 11 are views illustrating the scanning direction of the inkjet printing apparatus of FIG. 1.

Referring to FIGS. 1, 9, and 10, the head module PHM included in the inkjet printing apparatus ID may proceed with the printing process while moving in a scanning direction SD. For example, a substrate G may be placed on a stage ST, and a first printing process may be performed in a first region RE1 defined in the substrate G. The printing process may proceed continuously up to a second region RE2 in the substrate G while the stage ST moves in an opposite direction to the scanning direction SD. However, the disclosure is not limited thereto. For example, the stage ST may be fixed and the head module PHM may move.

The head module PHM of the inkjet printing apparatus ID may include a plurality of head packs HP1, HP2, and HP3. Each of the plurality of head packs HP1, HP2, and HP3 may include a plurality of heads. In an embodiment, each of the plurality of head packs HP1, HP2, and HP3 may have substantially the same structure.

For example, the first head pack HP1 may include the first head HE1, the second head HE2, the third head HE3, a fourth head HE4, a fifth head HE5, and a sixth head HE6. In an embodiment, the first head HE1, the second head HE2, the third head HE3, the fourth head HE4, the fifth head HE5, and the sixth head HE6 may have substantially the same structure, respectively. Therefore, the following description will focus on the first head HE1.

For example, the plurality of heads (e.g., the first head HE1, the second head HE2, the third head HE3, the fourth head HE4, the fifth head HE5, and the sixth head HE6, or the like) may be located to have a certain angle (e.g., a pre-set angle) AN with respect to a virtual axis IML parallel to the scanning direction SD while the printing process is in progress.

For example, first to hundredth nozzles may be included in each of the plurality of heads HE. For example, each of the first to hundredth nozzles may have different discharge characteristics. For example, the discharge amount may take a parabolic curve as it moves from the first nozzle to the hundredth nozzle. If the discharge amount is uneven, pixel characteristics may vary. To improve the uniformity of the discharge amount, the nozzles may be combined to discharge. For example, as the plurality of heads are located at an angle, an ejection timing may be distributed. For example, the angle AN may be set such that a pitch of the nozzles due to the combination of the plurality of nozzles being discharged is constant.

However, the disclosure is not limited thereto. For example, the plurality of heads HE may be located side by side in the horizontal direction. In addition, the angle AN may be changed in various ways.

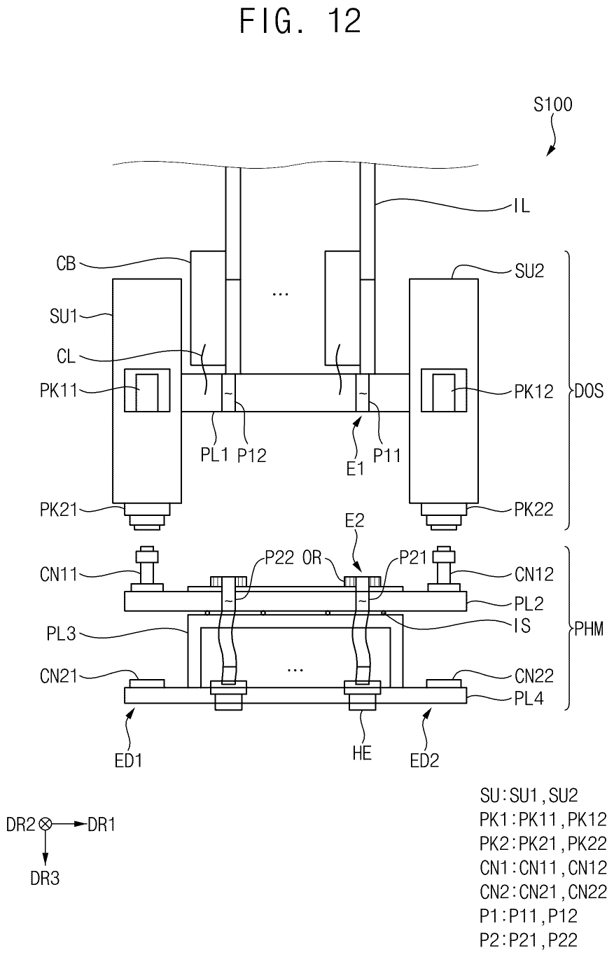

FIGS. 12 to 16 are views illustrating an assembly method of an inkjet printing apparatus according to one or more embodiments of the disclosure.

For example, FIGS. 12 to 16 are views illustrating the assembly method of the inkjet printing apparatus ID of FIG. 1. Herein, some repeated descriptions of the inkjet printing apparatus ID described above with reference to FIGS. 1 to 11 may be omitted or simplified.

Referring to FIG. 12, in one or more embodiments, the head module PHM including the plurality of head HE may be located under the docking module DOS (S100).

In one or more embodiments, the inkjet printing apparatus (e.g., the inkjet printing apparatus ID of FIG. 1) may include the docking module DOS and the head module PHM.

The head module PHM may include a plurality of heads HE. The inkjet printing apparatus according to one or more embodiments of the disclosure may be used when replacing at least one of the plurality of heads HE.

Referring to FIGS. 1 and 13, in one or more embodiments, the head module PHM may move in the opposite direction to the third direction DR3 by a first operating distance D1, and the head module PHM may be primary chucked by the docking module DOS (S200).

In one or more embodiments, the primary chucking may be performed by the first pickers PK1 included in the docking module DOS. For example, the first pickers PK1 may include the air chuck. However, the disclosure is not limited thereto.

In one or more embodiments, in the primary chucking task, the origin may be defined by picking the first end ED1 of the fourth plate PL4, and the rotational movement of the fourth plate PL4 may be restricted by picking the second end ED2 of the fourth plate PL4. The second end ED2 of the fourth plate PL4 may be opposite the first end ED1 in the first direction DR1. By picking the second end ED2 after picking the first end ED1, the fourth plate PL4 may not rotate.

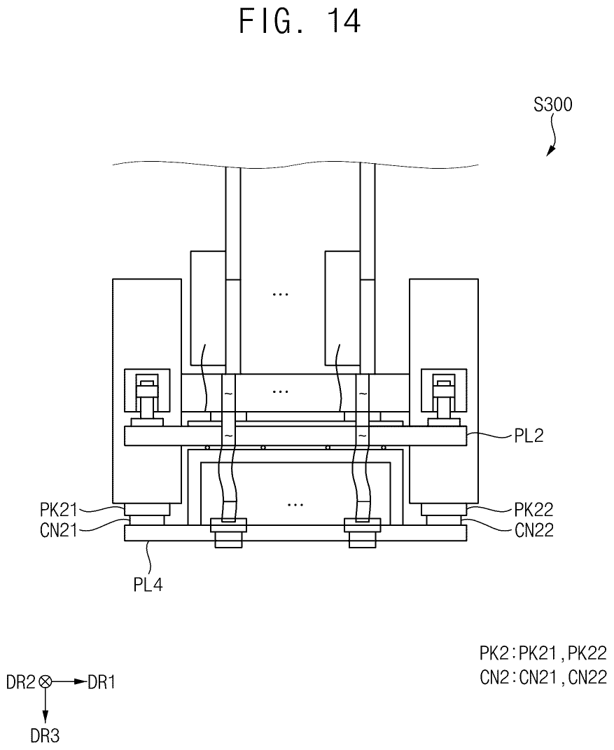

Referring to FIGS. 1 and 14, in one or more embodiments, the flow path may be formed as the head module PHM and the docking module DOS come into contact (e.g., close contact) (S300).

In one or more embodiments, by moving the second plate PL2 in the opposite direction to the third direction DR3, bringing into contact (e.g., close contact) the first plate PL1 and the second plate PL2, communicating the second end E2 of the second flow path P2 formed in the third direction in the second plate PL2 and the first end E1 of the first flow path P1 formed in the third direction DR3 in the first plate PL1, the flow path through which the ink flows may be defined (e.g., formed or completed).

In one or more embodiments, the inkjet printing apparatus ID for the large substrate may include the plurality of heads HE. Each of the plurality of flow paths may be connected to each of the plurality of heads HE.

For example, the plurality of heads HE may include the first head HE1 and the second head HE2. The first head HE1 and the second head HE2 may be located to be spaced apart from each other in a direction (e.g., the first direction DR1).

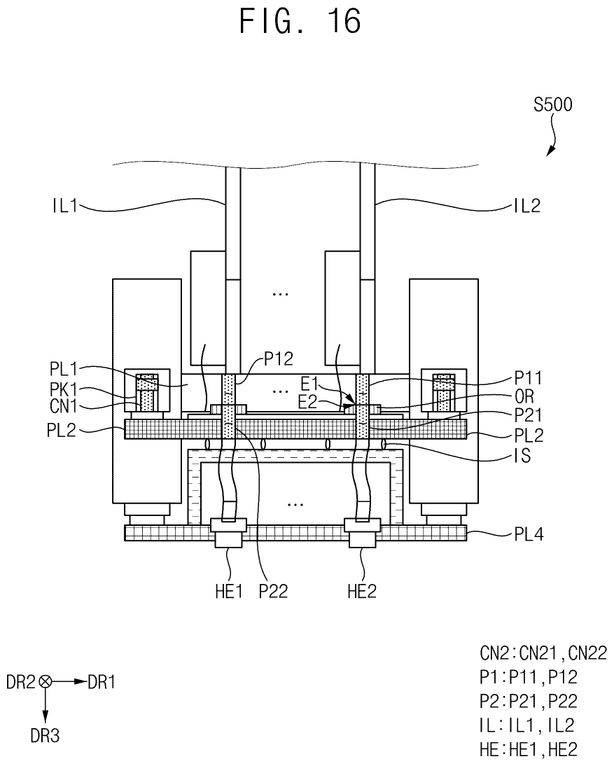

For example, the plurality of flow paths may be completed by connecting each of the plural ink-fed wiring IL to each of the plural heads HE on a 1:1 basis. A plurality of ink supply wiring IL may be part of a route that receives the ink from the ink tank and delivers the ink to the plurality of flow paths. For example, the ink supply wiring IL may be plural (see, e.g., sixteen first ink supply wiring IL1 and second ink supply wiring IL2 in FIG. 16).

For example, the plurality of flow paths may be completed by connecting each of the plurality of ink supply lines IL to each of the plurality of heads HE in a 1:1 ratio. The plurality of ink supply lines IL may be part of a path that receives the ink from an ink tank and delivers the ink to the plurality of flow paths. For example, the ink supply line IL may be plural (e.g., refer to a first ink supply line IL1 and a second ink supply line IL2 of FIG. 16).

In one or more embodiments, the first flow path P1 may be formed in the first plate PL1 in the third direction DR3. The first flow path P1 may include a first first flow path P11 and a second first flow path P12. A second flow path P2 may also be formed in the second plate PL2 in the third direction DR3. The second flow path P2 may include a first second flow path P21 and a second second flow path P22.

In one or more embodiments, an end of the first flow path P1 (e.g., the first end E1 of the first first flow path P11) may communicate with another end of the second flow path P2 (e.g. the second end E2 of the first second flow path P21. At this time, by contact (e.g., close contact) with the first plate PL1 and the second plate PL2, the ends may communicate at the same time. Accordingly, embodiments of the disclosure may be easier and simpler than the assembly method of the inkjet printing device according to the comparative embodiment of connecting the plurality of flow paths one by one, and the plurality of flow paths may be quickly connected to the plurality of heads HE.

In the above, for convenience of explanation, it has been described that the plurality of heads HE includes two heads, each of the two heads includes one flow path, and one ink supply path is connected. However, the disclosure is not limited thereto. For example, the plurality of heads HE may include three or more heads. In this case, the number of the plurality of flow paths connected to each of the three heads, and the number of the plurality of ink supply lines IL or the like may be changed in various ways.

In one or more embodiments, the end of the first flow path P1 (e.g., the first end E1 of the first first flow path P11) may be sealed by the rebound elastic force of the end of the second flow path P2 (e.g., the second end E2 of the first second flow path P21. For example, the rebound elastic force may be provided by the O-ring OR. However, the disclosure is not limited thereto.

In the above, for convenience of explanation, the description focuses on the plurality of flow paths; however, the disclosure is not limited thereto. For example, the assembly method of the inkjet printing apparatus may precisely align the head module PHM, and connects and detaches at once the plurality of lines (e.g., control lines, or the like) connected to each of the plurality of heads HE. Accordingly, the attachment/detachment precision of the head module PHM may be relatively improved and the attachment/detachment time of the head module PHM may be reduced.

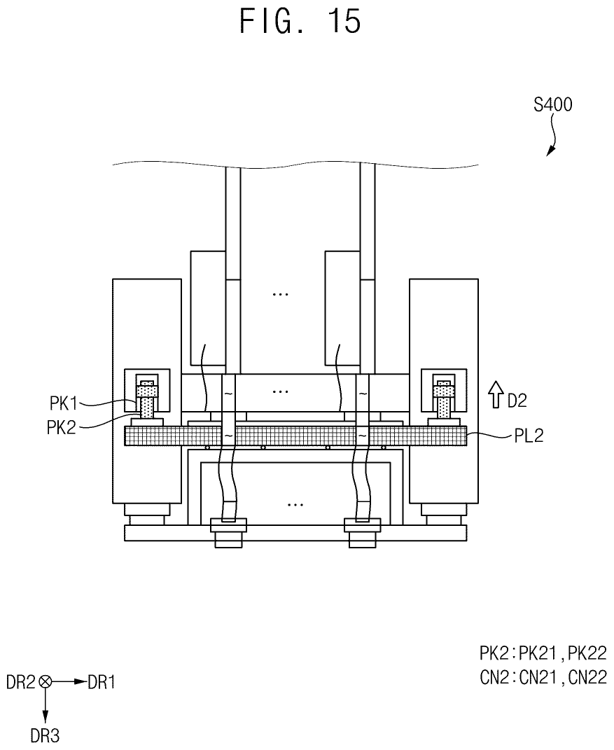

Referring to FIG. 15, in one or more embodiments, the head module PHM may move in the opposite direction opposite to the third direction DR3 by a second operating distance D2 different from the first operating distance D1, and the head module PHM may be secondary chucked by the docking module DOS (S400).

In one or more embodiments, the first operating distance D1 may be greater than the second operating distance D2. For example, the second plate PL2 may move by the first operating distance D1 and come into contact (e.g., close contact) with the first plate PL1 to define the plurality of flow paths. The fourth plate P4 may be precisely moved by the second operating distance D2 to align the plurality of heads HE with greater precision.

In one or more embodiments, the secondary chucking may be performed by second pickers PK2 included in the docking module DOS. For example, the second pickers PK2 may include the air chuck. However, the disclosure is not limited thereto.

In one or more embodiments, the first chucking and the second chucking may be vibratingly separated. In other words, during the secondary chucking, only the second plate PL2 may move in the opposite direction to the third direction DR3, and the fourth plate PL4 may not move in the opposite direction to the third direction DR3.

In one or more embodiments, a plurality of heads HE may be mounted on the fourth plate PL4, the third plate PL3 may be formed to cover upper portions of the plurality of heads HE on the fourth plate PL4, and the elastic body may be located on the third plate PL3. In one or more embodiments, the elastic body may be elastically deformed in the first direction DR1, the second direction DR2, and the third direction DR3. Accordingly, in a case in which the second plate PL2 is pulled in the opposite direction to the third direction DR3, the elastic body is deformed, and the fourth plate PL4 may be vibratingly separated from the second plate PL2.

The alignment precision of the head module PHM may be performed by the fourth plate PL4, the second pickers PK2, and the second connection parts CN2, automatic attachment, and detachment of the plurality of lines connected to each of the plurality of heads HE (e.g., the flow path and the control line, or the like) may be performed by the second plate PL2, the first pickers PK1, and the first connection parts CN1 and the fourth plate PL4 may be separated vibratingly such that there is no interference between the alignment and the automatic attachment and detachment.

Referring to FIG. 16, in one or more embodiments, the chucking head module PHM may be aligned in the first direction DR1 and the second direction DR2 by the docking module DOS (S500). That is, the head module PHM may be precisely aligned in the horizontal direction by the docking module DOS.

In the above, it has been described that the head module PHM is aligned after forming the flow path (S300); however, the disclosure is not limited thereto. In the assembly method of the inkjet printing device, the flow path may be formed S300 after aligning the head module PHM (S500).

In one or more embodiments, the head module PHM may be aligned according to a certain (e.g., preset) value to ensure repeatability. In one or more embodiments, before locating the head module PHM under the docking module DOS (S100), the docking module DOS may store the position at which the primary chucking the head module PHM is performed. Additional steps may be included. For example, the primary chucking position may be stored in the controller CON of FIG. 5.

In one or more embodiments, the discharge uniformity may be relatively improved by locating the plurality of heads HE such that a timing of use of the plurality of nozzles included in the plurality of heads HE included in the head module PHM do not overlap. In one or more embodiments, before locating the head module PHM under the docking module DOS (S100), the plurality of heads HE may be located so as to have the certain (e.g., preset) angle (e.g., the angle AN of FIG. 9) with a virtual reference line (e.g., the virtual reference line IML of FIG. 9 extending in a parallel direction with proceeding direction of the inkjet printing process (e.g., the scan direction SD of FIG. 9)).

An inkjet printing apparatus according to embodiments of the disclosure may be applied to a process of manufacturing a display device included in a computer, laptop, mobile phone, smartphone, smart pad, PMP, PDA, MP3 player, or the like.

Although the above disclosure has been provided with reference to some embodiments of the invention, it is to be understood that a person with ordinary knowledge in the field of technology may modify and change the invention in various ways within the scope of the ideas and areas of the invention, as set forth in the claims.

What is claimed is:

1. An inkjet printing apparatus comprising:
a first plate extending in a first direction and a second direction;
first and second supports extending in a third direction crossing the first direction and the second direction, and located at opposite ends of the first plate;
first pickers located at end areas of the first and second supports;
second pickers located to have an offset in the third direction with the first pickers at the end areas of the first and second supports, and having greater alignment precision than the first pickers;
a second plate extending in the first direction and the second direction and spaced apart from the first plate in the third direction;
first connection parts located on the second plate, and connected to the first pickers to bring the second plate in contact with the first plate;
a fourth plate extending in the first direction and the second direction and spaced apart from the second plate in the third direction, and a plurality of heads mounted on an upper surface; and
second connection parts located on the fourth plate, and connected to the second pickers to align the fourth plate in the first direction and second direction.

2. The inkjet printing apparatus of claim 1, wherein
a first flow path is defined in the third direction in the first plate,
a second flow path is defined in the third direction in the second plate, and
a first end of the first flow path and a second end of the second flow path communicate if the first plate and the second plate are in contact.

3. The inkjet printing apparatus of claim 2, further comprising:
an O-ring on the second plate,
wherein the first end and the second end are sealed by the O-ring if the second plate moves toward the first plate in an opposite direction to the third direction.

4. The inkjet printing apparatus of claim 2, wherein a plurality of flow paths through which an ink flows and connected to each of the plurality of heads and each of the plurality of flow paths is defined if the second plate is in contact with the first plate.

5. The inkjet printing apparatus of claim 2, wherein
the second connection parts comprise a first second connection part and a second second connection part located at opposite vertices of the fourth plate facing in the first direction,
the first second connection part defines an origin, and
the second second connection part limits rotational movement of the fourth plate.

6. The inkjet printing apparatus of claim 1, further comprising:
a third plate extending in the first direction and the second direction and located on the fourth plate; and
a spacer located between the second plate and the third plate, and
wherein the spacer vibratingly separates the second plate and the fourth plate.

7. The inkjet printing apparatus of claim 6, wherein the spacer comprises an elastic body.

8. The inkjet printing apparatus of claim 6, wherein the elastic body is elastically deformable in the first direction, the second direction, and the third direction.

9. The inkjet printing apparatus of claim 1, wherein each of the plurality of heads is located to have a certain angle based on a virtual axis parallel to a scanning direction in which an inkjet printing process is performed.

10. The inkjet printing apparatus of claim 1, further comprising a controller configured to store a position where the second connection parts connect to the second pickers.

11. A method of assembling an inkjet printing apparatus, the method comprising:
locating a head module comprising a plurality of head modules under a docking module;
moving the head module in an opposite direction to a third direction by a first operating distance, and performing primary chucking of the head module by the docking module;
forming a flow path as the head module and the docking module come into contact;
moving the head module in the opposite direction to the third direction by a second operating distance different from the first operating distance, and performing secondary chucking of the head module by the docking module; and
aligning the head module in a first direction and a second direction crossing the third direction using the docking module.

12. The method of claim 11, wherein the forming of the flow path comprises: moving a second plate of the head module that extends in the first direction and the second direction in the opposite direction to the third direction, such that the second plate is in contact with a first plate of the docking module that extends in the first direction and the second direction; and
communicating a first end of a first flow path formed in the third direction in the first plate and a second end of a second flow path formed in the third direction in the second plate.

13. The method of claim 12, wherein the first end of the first flow path and the second end of the second flow path are sealed by a rebound elastic force in the forming of the flow path.

14. The method of claim 12, wherein
the first operating distance is greater than the second operating distance, and
the docking module chucks the head module using air.

15. The method of claim 12, wherein the primary chucking comprises:
defining an origin by picking a first end of a fourth plate of the head module that extends in the first direction and the second direction, is spaced apart from the second plate in the third direction, and on which the plurality of heads is mounted on an upper surface; and
limiting a rotational movement of the fourth plate by picking a second end facing the first end in the first direction.

16. The method of claim 15, wherein the primary chucking and the secondary chucking are vibrationally separated.

17. The method of claim 16, wherein the head module is formed by forming a third plate on the fourth plate to cover upper portions of the plurality of heads and locating an elastic body on the third plate.

18. The method of claim 17, wherein the elastic body is elastically deformed in the first direction, the second direction, and the third direction.

19. The method of claim 11, further comprising locating the plurality of heads to have a certain angle based on a virtual axis parallel to a scanning direction in which an inkjet printing process is performed before locating the head module under the docking module.

20. The method of claim 11, further comprising storing a position where the docking module primary chucks the head module, before locating the head module under the docking module.
